(19) United States
(12) Patent Application Publication
(10) Pub. No.: US 2004/0089930 A1
(43) Pub. Date: May 13, 2004

(54) Simplified stacked chip assemblies

(75) Inventor: Masud Beroz, Livermore, CA (US)

Correspondence Address: LERNER, DAVID, LITTENBERG,, KRUMHOLZ & MENTLIK, 600 SOUTH AVENUE WEST, WESTFIELD, NJ, 07090, US

(73) Assignee: Tessera, Inc., San Jose, CA (US)

(21) Appl. No.: 10/600,186

(22) Filed: Jun. 20, 2003

Related U.S. Application Data
(60) Provisional application No. 60/391,522, filed on Jun. 25, 2002.

(51) Int. Cl. H01L 23/02

(52) U.S. Cl. 257/678

(57) ABSTRACT

A semiconductor chip having contacts on a front surface is provided with pads and traces on the rear surface. These pads and traces desirably are not electrically connected to internal components within the chip. In a stacked assembly, a chip overlies the rear surface of the first-mentioned chip and is connected to the pads. The traces are connected to a substrate such as a circuit board, as by wire-bonding before applying the second chip, so that the second chip is electrically connected to the substrate through the pads and traces.

### CROSS-REFERENCE TO RELATED APPLICATIONS

The present application claims benefit of U.S. Provisional Patent Application Serial No. 60/391,522, filed Jun. 25, 2002, the disclosure of which is incorporated by reference herein.

### BACKGROUND OF THE INVENTION

The present invention relates to semiconductor chip assemblies and to components and methods for making such assemblies.

Typical semiconductor chips are planar, usually rectangular solid bodies having oppositely-directed front and rear surfaces and edges extending between these surfaces. A chip typically has contacts on the front surface which are electrically connected to the electronic components inside the chip. The length and width of the front and rear surfaces, referred to herein as the horizontal dimensions of the chip, typically are many times larger than the thickness of the chip or the dimensions of the edges, also referred to herein as the vertical dimension of the chip.

Chips ordinarily are mounted on circuit panels such as circuit boards with the front and rear surfaces of the chips parallel to the plane of the circuit board. Most commonly, each chip is provided in a package having terminals separate from the contacts of the chip itself, and the package is mounted to the circuit board. For example, a package may include a small dielectric element, commonly referred to as a chip carrier, having metallic terminals. The chip is mounted to the chip carrier with the front or rear surface of the chip facing the chip carrier and the contacts of, the chip are electrically connected to the terminals on the chip carrier by leads such as wire bonds or metallic strips provided on the chip carrier. The chip and leads typically are covered by an encapsulant. The packaged chip can be mounted to the circuit board by solder-bonding the terminals of the chip carrier to the circuit board. In other cases, “bare” or unpackaged chips are mounted directly to a circuit board with the front or rear surface of the chip facing the board.

To make the circuit board as small as possible, it is desirable to minimize the area of the circuit board occupied by each chip. One way to do this is to stack chips, one above the other, so that several chips can be mounted on an area of the circuit board approximately the same as the area required to mount a single chip. In one such arrangement, each chip is provided in a separate unit incorporating the chip and a chip carrier having peripheral regions which extend horizontally outwardly, beyond the edges of the chip. Each chip carrier has terminals in the peripheral regions. The units are stacked so that the chip in each unit is aligned with the chip of the adjacent units, and so that the peripheral regions and terminals of adjacent units are also aligned with one another. The terminals of adjacent units are connected to one another by conductors such as solder masses so as to form vertical connections extending through the stack. Such a stacked assembly can be mounted on a circuit panel. This arrangement can be used with chips of various types. However, it incurs the costs associated with the chip carriers.

If the chips to be incorporated in a stacked assembly have contacts only in edge regions, near the edges of their front surfaces, it is possible to make a stack by placing a smaller chip directly on the front surface of a larger chip. The rear surface of the smaller chip confronts a central region of the larger-chip front surface, leaving the contact-bearing edge regions of the larger chip exposed. The front surface of the smaller chip faces upwardly, away from the larger chip, so that the contacts of the smaller chip are also exposed. The contacts of both chips can be connected by wire bonds to a circuit board or chip carrier disposed below the larger chip. The wire bonds extend downwardly outside the edges of the larger chip. This arrangement can be used for more than two chips, provided that each chip in the stack is smaller than the chip below it. While this arrangement avoids the cost of separate chip carriers for each chip in the stack, it is not suitable for packaging chips which have contacts near the centers of their front surfaces. Moreover, this arrangement is not suitable for packaging several identical chips in a stack as required, for example, where identical memory chips are to be stacked.

Further improvements in stacked chip assemblies and in chips suitable for stacking would be desirable.

### SUMMARY OF THE INVENTION

One aspect of the invention provides an improved chip. A semiconductor chip according to this aspect of the invention preferably has a body with oppositely-directed front and rear surfaces, contacts on the front surface and internal components such as active semiconductor devices or passive components within the body. The internal components are electrically connected to the contacts on the front surface. The chip preferably also has pads on the rear surface, at least some of these pads being electrically isolated from the internal components and has traces on the rear surface electrically connected to the pads. Most preferably, the body has edges bounding the front and rear surfaces and the traces include bonding points disposed in the vicinity of said edges. The pads may be disposed near the center of the rear surface.

A further aspect of the invention provides an assembly of plural chips. A chip assembly according to this aspect of the invention desirably includes a first semiconductor chip, which may be a chip as discussed above, including a first body with oppositely-directed front and rear surfaces, and having internal components within the first body. The first semiconductor chip also has contacts on the front surface connected to the internal components. The first semiconductor chip most preferably has pads on the rear surface of the first body and traces extending from these pads along the rear surface of the first body. The assembly further includes a second semiconductor chip including a second body with oppositely-directed front and rear surfaces, the second semiconductor chip having internal components within the second body and contacts on the front surface of the second semiconductor chip.

Most preferably, the second semiconductor chip is mounted on the first semiconductor chip so that the second semiconductor chip overlies the rear surface of the first semiconductor chip, and the contacts of the second semiconductor chip being electrically connected to the pads of the first semiconductor chip. In one arrangement, the front surface of the second semiconductor chip confronts the rear surface of the first semiconductor chip. The contacts of the second semiconductor chip may be bonded to the pads of the first semiconductor chip by masses of electrically conductive bonding material.

The assembly desirably also includes a substrate, the chips being mounted on the substrate, preferably with the front surface of the first semiconductor chip facing toward the substrate. The contacts of the first semiconductor chip desirably are electrically connected to the substrate. The traces on the rear surface of the first semiconductor chip desirably are also connected to the substrate so that the contacts of the second semiconductor chip are connected to the substrate through the pads and traces on the rear surface of the first semiconductor chip. In such an arrangement, the pads and traces on the rear surface of the first semiconductor chip act in much the same manner as the conductive elements of a chip carrier. However, this function is performed without the need for an additional, separate component.

The assembly may include bonding wires extending between the traces and the substrate, the traces being electrically connected to the substrate through the bonding wires. The bonding wires typically are connected to the traces on the rear surface of the first semiconductor adjacent the edges of the first semiconductor chip. Thus, even where the contacts of the second semiconductor chip and the pads on the rear surface of the first semiconductor chip are disposed remote from the edges of such chip, it is still practical to use simple, inexpensive bonding wires to make the connection to the substrate.

The substrate may be a circuit board, in which case the chips can be directly connected to the circuit board without the use of a package substrate. Alternatively, the substrate may be a package substrate having terminals suitable for mounting to a circuit board. Even where such a package substrate is used, however, only one such substrate need be used; there is no need for an additional substrate for every chip in the assembly.

The assembly can include more than two chips. For example, the second chip may have pads and traces on its rear surface, and the assembly may include a third semiconductor chip overlying the rear surface of the second semiconductor chip and electrically connected to the pads of the second chip. The traces on the rear surface of the second chip may be connected to the substrate, as, for example, by bonding wires joining these traces near the edges of the second chip.

Yet another aspect of the invention provides methods of making a semiconductor chip assembly. A method according to this aspect of the invention preferably includes the step of mounting a first semiconductor chip to a substrate so that a front surface of the first semiconductor chip faces toward the substrate and a rear surface of the first semiconductor chip faces away from the substrate, and so that terminals of the first semiconductor chip on the front surface thereof are electrically connected to the substrate. The method desirably further includes making electrical connections between traces on the rear surface of the first semiconductor chip and the substrate to thereby connect pads on the rear surface of the first semiconductor chip with the substrate, and mounting a second semiconductor chip to the first semiconductor chip so that contacts of the second semiconductor chip are electrically connected to the pads of the first semiconductor chip. Thus, the second semiconductor chip is connected to the substrate through the pads and traces on the rear surface of the first semiconductor chip.

The step of making electrical connections to the traces on the rear surface of the first chip desirably includes wire-bonding the traces of the first semiconductor chip to the substrate. The wire-bonding operation may be performed before mounting the second semiconductor chip on the first semiconductor chip. As discussed above in connection with the assembly, the method can be used to assemble more than two chips; desirably, the traces on the rear surface of each chip are wire-bonded or otherwise connected to the substrate before placing the next chip.

### BRIEF DESCRIPTION OF THE DRAWINGS

FIG. 1 is a diagrammatic sectional view of a chip according to one embodiment of the invention.

FIG. 2 is a diagrammatic top plan view of the chip shown in FIG. 1.

FIG. 3 is a diagrammatic elevational view of a subassembly including the chip shown in FIGS. 1-2.

FIGS. 4 and 5 are views similar to FIG. 3 but depicting the subassembly of FIG. 3 in conjunction with other components.

FIG. 6 is a diagrammatic sectional view of a subassembly according to a further embodiment of the invention.

FIGS. 7-9 are views similar to FIG. 6 but depicting the subassembly of FIG. 6 in conjunction with other components.

FIG. 10 is a diagrammatic elevational view depicting an assembly in accordance with a further embodiment of the invention.

### DETAILED DESCRIPTION

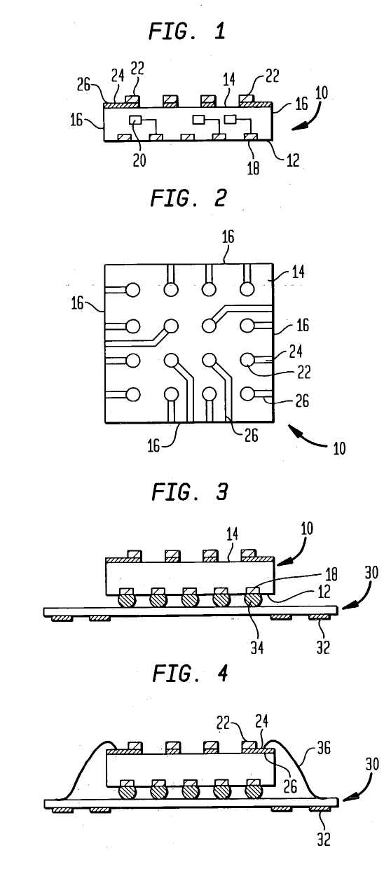

An assembly in accordance with one embodiment of the invention includes a first semiconductor chip 10 (FIGS. 1 and 2) having a chip body with a front surface 12, a rear surface 14 and edges 16 extending between these surfaces and bounding the front and rear surfaces. The chip has contacts 18 on front surface 12 and has internal electronic components, schematically depicted at 20, within the chip body. In most semiconductor chips, these internal electronic components include “active” components such as transistors, diodes, logic gates and myriad other components assembled in circuitry which can be of any type. However, some semiconductor chips are also fabricated with only “passive” components, i.e., resistors, capacitors and/or inductors. As used in this disclosure, the term “semiconductor chip” refers to a unitary body of material including one or more semiconductors, and which may also include other materials such as insulators and metals within the body. Also, the term “semiconductor chip” should be understood as including the passivation layer which is commonly provided on exposed surfaces of the unitary body and which forms a part of the unitary body. Such passivation layers can include, for example, oxide or nitride films formed in the deposition equipment used to apply the semiconductor layers and can also include layers of substances such as dielectric polymers or metals which are bound to the other portion of the unitary body and, hence, form a part of the body itself. Further, although contacts 18 are referred to herein as being “on” surface 12, it should be understood that this does not imply that the terminals necessarily project above the surrounding portions of surface 12. For example, the terminals may be flush with the remaining portions of the surface, recessed slightly into the body, or project above the remaining portions of the surface, provided that the contacts are exposed for connection at such surface.

Chip 10 also has electrically conductive pads 22 and traces 24 on rear surface 14. Here again, it is not essential that the pads and traces project from the remaining portions of the surface as depicted, for example, in FIG. 1; the pads and traces may be recessed, flush or projecting. Pads 22 and traces 24 are carried on the chip itself, i.e., on one of the semiconductor, passivation or other layers of the chip body, so that the pads and traces form an integral part of the chip. The pads and traces may be formed lithographically on the rear surface of the chip, as by laminating a metallic layer and then etching the metallic layer to form the pads and traces on the rear surface; by depositing the metal to form the pads and traces on the rear surface using processes such as sputtering, evaporative deposition, chemical vapor deposition or the like, and then etching the metallic layer; or by depositing metal after providing a mask such as a photoresist (not shown) in areas where the metallic deposits are desired and then stripping away the photoresist. The processes used to form the pads and traces may be substantially the same as those commonly used to form contacts on the front surface of the chip. Most commonly, chips 10 are fabricated in a wafer using conventional semiconductor processing equipment to form the internal components 20 and contacts 18 of numerous chips. Pads 22 and traces 24 desirably are fabricated while these numerous chips are still in the form of a wafer, i.e., before the wafer is severed to provide individual chips. Depending upon the electrical design of the chip and of the overall circuit, pads 22 may or may not be connected to the internal components 20 of the first chip. For example, the first chip may be made as a standard semiconductor chip having all of the required connections to internal components through the contacts 18 on the front surface. Wafers treated to form such chips may be either severed to make conventional chips or treated as discussed above to form the pads and traces on the rear surfaces as desired. Stated another way, no design changes in the internal components and circuitry of the chip or in the masks and process steps used to form such internal components are required. In other cases, it may be desirable to provide some connections to some or all of the pads or traces from the internal components, so as to simplify routing within the chip.

As best seen in FIG. 2, traces 24 extend from pads 24 outwardly toward the edges 16 bounding rear surface 14 and provide bonding points 26 adjacent the edges 16. The bonding points are also exposed on the rear surface 14 so that these points are accessible for connections as discussed below. Depending upon the width and composition of traces 24, the bonding points may have the same width and composition as the remainder of the trace or may be enlarged in width relative to the remainder of the trace. The pads, bonding points or both may have additional materials to facilitate bonding as, for example, gold plating.

Chip 10 is mounted on a substrate 30 (FIG. 3) so that the front surface 12 of the chip faces toward the substrate and so that contacts 18 on the front surface are connected to conductive features (not shown) in or on the substrate. The particular substrate illustrated in FIG. 3 is a package substrate and has terminals 32 on the opposite surface from chip 10. These terminals are arranged for connection to an external circuit board, as discussed below. Contacts 18 may be bonded to the conductive features of the substrate 30 by masses of bonding material 34 as, for example, solder balls, solid core solder balls, polymeric bonding materials or other bonding materials. Thus, the first chip is secured to the substrate with the rear surface 14 facing upwardly, away from the substrate.

In the next step of the process (FIG. 4), traces 24 and hence pads 22 are electrically connected to other conductive features on the substrate by wire bonds 36 extending between the bonding points 26 of the traces and other conductive features (not shown) of substrate 30. Depending upon the desired circuit, the conductive features of the substrate may include traces which interconnect some or all of the contacts 18 with some or all of terminals 32; interconnect some or all of wire bonds 36 and hence some or all of pads 22 with terminals 32; and interconnect some or all of the wire bonds 36 and pads 22 with some or all of the contacts 18. The conductive features of the substrate also may optionally connect some or all of contacts 18 with one another and/or some or all of wire bonds 36 and pads 22 with one another so as to provide internal routing for signals and/or power or ground voltages within a single chip.

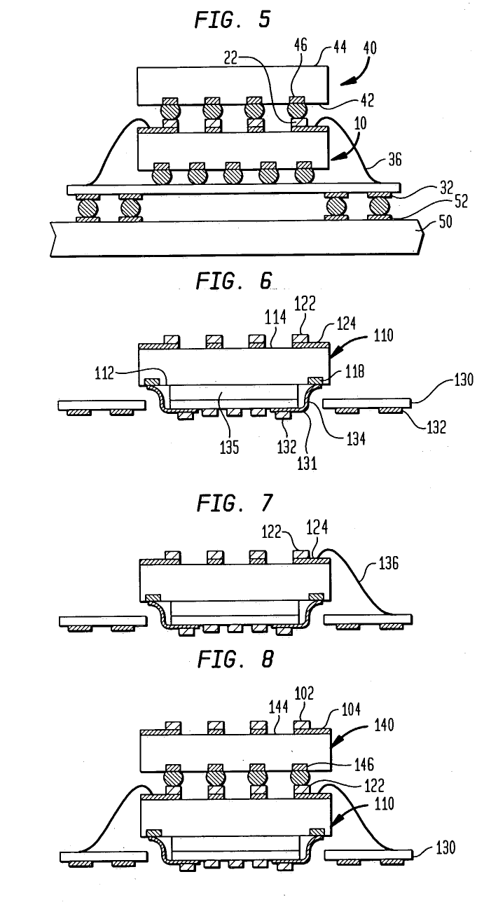

In the next stage of the process, a second semiconductor chip 40 having a body with a front surface 42, rear surface 44 and contacts 46 connected to internal components (not shown) within the second chip is mounted on the first chip 10 so that the contacts 46 are bonded to and electrically connected to pads 22 on the rear surface of the first chip. Thus, the contacts 46 are interconnected with substrate 30 and, hence, with terminals 32. If some or all of the pads 22 on the rear surface of the first chip are connected to internal components of the first chip, the second chip also will be connected to the internal components of the first chip. The resulting assembly provides a multi-chip, stacked package which can be handled and mounted as a unit. For example, as shown in FIG. 5, the package can be connected to a circuit panel 50 by bonding terminals 32 to pads 52 on the circuit panel. Alternatively, where terminals 32 are arranged to accommodate other mounting processes, these other mounting processes can be used. For example, terminals 32 may be pins, leads or other conventional features commonly used to connect and secure a chip package to a circuit panel and the mating features of the circuit panel may be arranged accordingly. Thus, where terminals 32 are in the form of pins, the circuit panel may be provided with or replaced by a socket having apertures arranged to receive the pins.

A chip assembly according to a further embodiment of the invention has a first chip 110 similar to the first chip 10 discussed above, in that the first chip 110 has contacts 118 on its front surface 112 and pads 122 and traces 124 on its rear surface 114. However, the contacts 118 of the first chip are connected to conductive features 131 of substrate 130 by leads 134 extending between the substrate and the first chip. These leads may be flexible and the first chip may be mechanically secured to the substrate by structures such as a compliant layer 135 which permits some movement of the substrate relative to the first chip. The mounting arrangements for the first chip may be, for example, as shown in any or all of the following U.S. patents, the disclosures of which are incorporated by reference herein: U.S. Pat. Nos. 5,148,266; 5,148,265; 6,054,756; 5,489,749; 5,679,977; 5,518,964. As in the embodiment discussed above, substrate 130 is a package substrate and includes terminals 132 adapted for connection to an external circuit such as to a circuit panel. In the embodiment illustrated, some of these terminals are disposed on a central region of substrate 130 which is aligned with the first chip 110. Also, in the particular arrangement illustrated, the contacts 118 of the chip are disposed adjacent the edges 116 of the chip body so that the leads 134 and conductive features 131 which connect the terminals 118 “fan-in” or extend inwardly toward the geometric center of the chip surface from the contacts 118 towards the terminals 132 on this central region of the substrate.

Once again, the traces 124 and pads 122 are electrically connected to substrate 132 by wire bonds 136 (FIG. 7) and a second chip 140 is mounted on the first chip by bonding the contacts 146 of the second chip to the pads 122 on the rear surface of the first chip, as depicted in FIG. 7. In this embodiment, second chip 140 has additional pads 102 and traces 104 on its rear surface 144 so that these pads and traces face upwardly, away from the first chip 110 and substrate 130 when the second chip is mounted on the first chip.

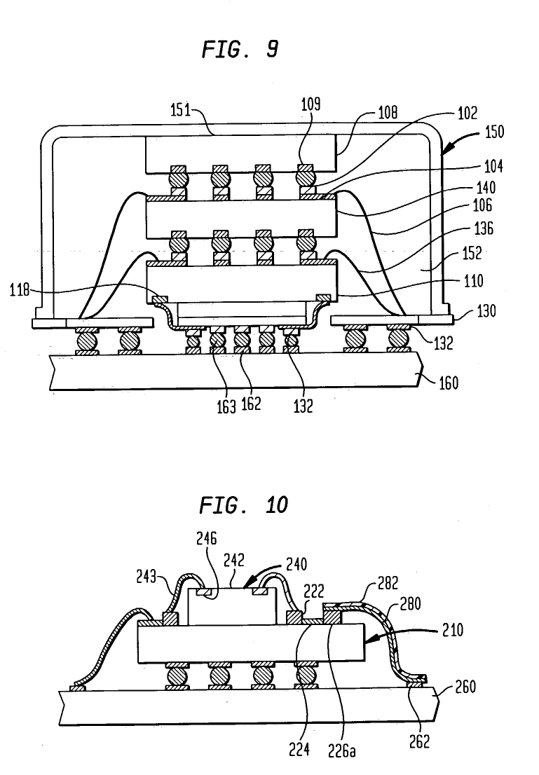

In the next stage of the process, the traces 104 and hence pads 102 of the second chip are connected by additional wire bonds 106 to the conductive features of substrate 130 as depicted in FIG. 8. Following completion of these additional wire bonds, a third semiconductor chip 108 (FIG. 9) is mounted on the second chip 140 and electrically connected to pads 102 on the rear surface of the second chip, as by bonding contacts 109 on the front surface of the third chip to pads 102 on the rear surface of the second chip. A thermally-conductive, preferably metallic heat spreader or “can” 150 is secured to the rear surface 151 of the third chip. The space surrounding the chips, between spreader 150 and substrate 130, desirably is filled with an encapsulant 152. The encapsulant preferably is a dielectric material and desirably extends into the spaces between the chips so that it surrounds the masses of bonding material used to connect the chips to one another. Optionally, different portions of the encapsulant may have different physical properties as, for example, different modulus of elasticity. The encapsulant also may be loaded with a dielectric, thermally conductive material as, for example, silicone nitride. Once again, the finished assembly provides a packaged chip assembly which can be mounted to an external circuit such as a circuit panel 160 in the manner discussed above so as to connect terminals 132 to conductive features such as pads 162 on the circuit panel. In use, differential thermal expansion of circuit panel 160 and chip 110 causes the contacts 118 of the first chip 110 to move somewhat relative to the pads 162 on the circuit panel. As discussed in the foregoing patents incorporated by reference herein, moveability of terminals 132 allows a significant portion of this relative movement to be accommodated by movement of the terminals 132 on substrate 130 relative to the first chip 110 and relative to the contacts 118 of the first chip. This, in turn, alleviates stresses on the bonding material 163 used to connect the terminals 132 and pads 162. The wire bonds 106 and 136 can flex and allow movement of terminals 132 relative to the chips. Chips 110, 140 and 108 desirably are formed from similar materials as, for example, where all are formed predominantly from silicon-based semiconductor materials. Moreover, the pads and bonding materials which interconnect these chips provide good thermal communication between adjacent chips. The thermal conductivity of the encapsulant also contributes to such thermal communication between adjacent chips. These factors tend to minimize differential thermal expansion between adjacent chips and enhances the reliability of the bonds between adjacent chips.

Numerous variations and combinations of the features discussed above can be utilized. For example, the assembly of FIG. 10 has a second chip 240 mounted in face-up orientation on the first chip 210, so that the contact-bearing or front surface 242 faces upwardly, away from the first chip 210. The contacts 246 of the second chip are connected to pads 222 and, hence, to traces 224 on the rear surface of first chip 210 by conductors such as wire bonds 243. Also, the traces 224 on the rear surface of the first chip need not define bonding pads at or adjacent the periphery of the first chip. For example, some of the traces 224 terminate at bonding pads 226a which are remote from the periphery of the first chip. Further, the traces on the rear surface of the first chip need not be connected to the substrate by wire bonds. Thus, as illustrated in FIG. 10, traces 224 are connected to pads 262 on substrate 260 by a tape-like structure including traces 280 and a polymeric backing 282. Other forms of connectors can be employed. Here again, however, the traces 224 on the rear surface of the first chip serve to redistribute the connections to the contacts of the second chip and also provide locations for making connections to such contacts. Further, the substrate need not be a package substrate. Substrate 260 is an ordinary circuit board and chip 210 is simply mounted directly to the circuit board using conventional “flip-chip” arrangements.

In the embodiments discussed above, the traces and pads are fabricated in situ on rear surfaces of the chips. In other arrangements, however, the traces and pads can be provided on a separate structure which is then fused or bonded with the rear surface of the appropriate chip so that such structure effectively becomes a permanent part, of the chip itself.

As these and other variations and combinations of the features discussed above can be employed, the foregoing description of the preferred embodiments should be taken by way of illustration rather than by way of limitation of the present invention.

1. A semiconductor chip having a body with oppositely-directed front and rear surfaces, contacts on said front surface and internal components within said body electrically connected to said contacts on said front surface, said chip also having pads on said rear surface electrically isolated from said internal components and traces on said rear surface electrically connected to said pads.

2. A chip as claimed in claim 1 wherein said internal components include active devices.

3. A chip as claimed in claim 1 wherein said internal components consist only of passive devices.

4. A chip as claimed in claim 1 wherein said body has edges bounding said front and rear surfaces and said traces include bonding points disposed in the vicinity of said edges.

5. A chip assembly comprising:
(a) a first semiconductor chip including a first body with oppositely-directed front and rear surfaces, said first semiconductor chip having internal components within said first body, contacts on the front surface connected to said internal components, said first semiconductor chip also having pads on the rear surface of said first body and traces extending from said pads along the rear surface of the first body;
(b) a second semiconductor chip including a second body with oppositely-directed front and rear surfaces, said second semiconductor chip having internal components within the second body and contacts on the front surface of the second semiconductor chip,
said second semiconductor chip being mounted on said first semiconductor chip so that said second semiconductor chip overlies said rear surface of said first semiconductor chip, said contacts of said second semiconductor chip being electrically connected to said pads of said first semiconductor chip.

6. A chip assembly as claimed in claim 5 wherein said front surface of said second semiconductor chip confronts said rear surface of said first semiconductor chip.

7. A chip assembly as claimed in claim 6 wherein said contacts of said second semiconductor chip are bonded to said pads of said first semiconductor chip by masses of electrically conductive bonding material.

8. A chip assembly as claimed in claim 5 or claims 6 or claim 7 further comprising a substrate, said chips being mounted on said substrate with said front surface of said first semiconductor chip facing toward said substrate, said contacts of said first semiconductor chip being electrically connected to said substrate, said traces of said first semiconductor chip also being electrically connected to said substrate so that said contacts of said second semiconductor chip are connected to said substrate through said pads and traces of said first semiconductor chip.

9. A chip assembly as claimed in claim 8 further bonding wires extending between said traces and said substrate, said traces being electrically connected to said substrate through said bonding wires.

10. A chip assembly as claimed in claim 9 wherein said first semiconductor chip has edges bounding said front and rear surfaces of said first body, and wherein said bonding wires are connected to said traces adjacent said edges.

11. A chip assembly as claimed in claim 8 wherein said contacts of said first semiconductor chip are connected to said substrate by masses of bonding material disposed between said contacts of said first semiconductor chip and said substrate.

12. A chip assembly as claimed in claim 8 wherein said contacts of said first semiconductor chip are connected to said substrate by leads extending between said contacts of said first semiconductor chip and said substrate.

13. A chip assembly as claimed in claim 8 wherein said substrate is a package substrate adapted for mounting on a circuit panel.

14. A chip assembly as claimed in claim 13 wherein said substrate has terminals adapted for connection to a circuit panel, said terminals being movable with respect to said first semiconductor chip.

15. A chip assembly as claimed in claim 8 wherein said second semiconductor chip has pads and traces on the rear surface of said second body, the traces of said second semiconductor chip being electrically connected to said substrate, the assembly further comprising a third semiconductor chip overlying said rear surface of said second semiconductor chip and electrically connected to said pads of said second semiconductor chip.

16. A method of making a semiconductor chip assembly comprising the steps of:
(a) mounting a first semiconductor chip to a substrate so that a front surface of the first semiconductor chip faces toward the substrate and a rear surface of the first semiconductor chip faces away from the substrate, and so that terminals of the first semiconductor chip on the front surface thereof are electrically connected to the substrate;
(b) making electrical connections between traces on the rear surface of the first semiconductor chip and the substrate to thereby connect pads on the rear surface of the first semiconductor chip with the substrate; and
(c) mounting a second semiconductor chip to the first semiconductor chip so that contacts of the second semiconductor chip are electrically connected to the pads of the first semiconductor chip, whereby the second semiconductor chip is connected to the substrate through the pads and traces on the rear surface of the first semiconductor chip.

17. A method as claimed in claim 16 wherein said step of making electrical connections includes wire-bonding the traces of the first semiconductor chip to the substrate.

18. A method as claimed in claim 17 wherein said wire-bonding step is performed before mounting the second semiconductor chip on the first semiconductor chip.

19. A method as claimed in claim 18 wherein said second semiconductor chip has said contacts on a front surface and said step of mounting the second semiconductor chip on the first semiconductor chip is performed so that said front surface of said second semiconductor chip confronts said rear surface of said first semiconductor chip.
